(19) United States
(12) Patent Application Publication
(10) Pub. No.: US 2015/0053135 A1
(43) Pub. Date: Feb. 26, 2015

(54) STRAP FOR PLASMA PROCESSING APPARATUS AND PLASMA PROCESSING APPARATUS HAVING THE SAME

(71) Applicant: Samsung Display Co., Ltd., Yongin-City (KR)

(72) Inventors: Yung-Bin CHUNG, Seoul (KR); Jun-Hyuck JEON, Asan-si (KR); Yeon-Taek JUNG, Cheonan-si (KR); Seok-Bae KO, Asan-si (KR); Myoung-Jae KIM, Asan-si (KR); Jin-Hyuck SONG, Asan-si (KR); Eun-A YU, Seoul (KR); Seung-Kyeng CHO, Hwaseong-si (KR); Ji-Hyun HAM, Suwon-si (KR)

(73) Assignee: Samsung Display Co., Ltd., Yongin-City (KR)

(21) Appl. No.: 14/187,471

(22) Filed: Feb. 24, 2014

(30) Foreign Application Priority Data
Aug. 22, 2013 (KR) 10-2013-0099599

(51) Int. Cl. H01J 37/32; C23C 16/509

(52) U.S. Cl. CPC H01J 37/32577; C23C 16/509; H01J 2237/327; H01J 2237/3323
USPC 118/723 E; 428/174

(57) ABSTRACT

A strap for a plasma processing apparatus includes a main body, and a protrusion pattern defined in the main body. The main body may include a binding part defined at opposing ends thereof. The protrusion pattern may include a protrusion.

This application claims priority to Korean Patent Application No. 10-2013-0099599, filed on Aug. 22, 2013, and all the benefits accruing therefrom under 35 U.S.C. §119, the disclosure of which is incorporated by reference herein in its entirety.

### BACKGROUND

(1) Field

The invention relates to a strap for a plasma processing apparatus and a plasma processing apparatus including the same. More particularly, the invention relates to a strap for a plasma processing apparatus capable of decreasing a disconnection of the strap.

(2) Description of the Related Art

Generally, a thin film deposition process is performed to form a thin film on a substrate. The thin film deposition process includes a physical vapor deposition (“PVD”) and a chemical vapor deposition (“CVD”).

The CVD may include low pressure chemical vapor deposition (“LPCVD”), atmospheric pressure chemical vapor deposition (“APCVD”), plasma enhanced chemical vapor deposition (“PEVCD”), high pressure chemical vapor deposition (“HPCVD”), etc.

The PEVCD may include a cleavage of a reactive gas by a plasma energy. Thus, the cleavage of the reactive gas and a deposition may be conducted in a low temperature.

A substrate in the PEVCD may be disposed on a susceptor which moves up and down for loading and unloading of the substrate. A strap may serve as a ground line for generating uniform plasma in a reaction chamber. The strap is disposed on a lower surface of the susceptor. Therefore, since the susceptor moves up and down for loading and unloading of the substrate, the strap may be formed using a flexible metal.

### SUMMARY

One or more exemplary embodiment provides a strap for a plasma processing apparatus capable of improving durability of thereof

One or more exemplary embodiment also provides a plasma processing apparatus having the above-mentioned strap.

In accordance with an exemplary embodiment of the invention, a strap for a plasma processing apparatus includes a main body; a binding part defined in the main body at opposing ends thereof; and a protrusion pattern defined in the main body and including a protrusion.

In an exemplary embodiment of the invention, the main body may include aluminum.

In an exemplary embodiment of the invention, a height of the protrusion may be within a range of about 0.5 centimeter (cm) to about 3 centimeters (cm).

In an exemplary embodiment of the invention, a width of the protrusion may be within a range of about 0.1 cm to about 3 cm.

In an exemplary embodiment of the invention, the strap may further include a coating layer on the protrusion pattern. The coating layer may include an engineering plastic or an inorganic material.

In an exemplary embodiment of the invention, the coating layer may include a plurality of layers including a first layer and a second layer. The first layer may be on the protrusion pattern and may include the engineering plastic. The second layer may be on the first layer and may include the inorganic material.

In an exemplary embodiment of the invention, the coating layer may include a plurality of layers including a first layer and a second layer. The first layer may be on the protrusion pattern and may include the inorganic material. The second layer may be on the first layer and may include the engineering plastic.

In an exemplary embodiment of the invention, a thickness of the coating layer may be within a range of about 0.1 micrometer (μm) to about 200 micrometers (μm).

In an exemplary embodiment of the invention, the engineering plastic may include polyether ether ketone or polyether aryl ketone.

In an exemplary embodiment of the invention, the inorganic material may include Al2O3, ZrO2 or Y2O3.

In an exemplary embodiment of the invention, the protrusion pattern may be defined in an entirety of the main body.

In an exemplary embodiment of the invention, the strap may further include a coating layer on an entirety of the protrusion pattern. The coating layer may include an engineering plastic or an inorganic material.

In accordance with an exemplary embodiment of the invention, a plasma processing apparatus includes a first electrode, a second electrode, a strap, a substrate support and a reaction chamber.

A radio frequency power is applied to the first electrode. The second electrode faces the first electrode. The strap is on a lower surface of the second electrode. The strap includes a main body, a binding part defined in the main body at opposing ends thereof, and a protrusion pattern defined in the main body and including a protrusion. The substrate support is on a lower surface of the second electrode. The reaction chamber receives the first electrode, the second electrode, the strap and the substrate support.

In an exemplary embodiment of the invention, the plasma processing apparatus may include a gas injection portion on an upper surface of the first electrode.

In an exemplary embodiment of the invention, the second electrode may be a susceptor.

In an exemplary embodiment of the invention, a height of the protrusion may be within a range of about 0.5 cm to about 3 cm.

In an exemplary embodiment of the invention, a width of the protrusion may be within a range of about 0.1 cm to about 3 cm.

In an exemplary embodiment of the invention, the plasma processing apparatus further includes a coating layer on the protrusion pattern. The coating layer includes an engineering plastic or an inorganic material.

In an exemplary embodiment of the invention, the engineering plastic may include polyether ether ketone or polyether aryl ketone.

In an exemplary embodiment of the invention, the inorganic material may include Al₂O₃, ZrO₂ or Y₂O₃.

In accordance with one or more exemplary embodiment of the invention, a stress applied to the strap may be adequately distributed therethrough. The strap may decrease a disconnection of the strap by reducing or effectively preventing a strengthening thereof by fluorine permeation during a deposition process performed in the reaction chamber. Thus, an interruption of a deposition process, such as to replace a strap, may be decreased.

### BRIEF DESCRIPTION OF THE DRAWINGS

The above and other features of this disclosure will become more apparent by describing in detailed exemplary embodiments thereof with reference to the accompanying drawings, in which:

FIG. 1 is a cross-sectional view illustrating an exemplary embodiment of a plasma processing apparatus in accordance with the invention;

FIG. 2 is a plan view illustrating an exemplary embodiment of a strap in FIG. 1;

FIG. 3 is a cross-sectional view illustrating the strap in FIG. 2;

FIG. 4 is a plan view illustrating another exemplary embodiment of a strap in accordance with the invention;

FIG. 5 is a cross-sectional view illustrating the strap in FIG. 4;

FIG. 6 is a plan view illustrating still another exemplary embodiment of a strap in accordance with the invention;

FIG. 7 is a cross-sectional view illustrating the strap in FIG. 6;

FIG. 8 is a plan view illustrating yet another exemplary embodiment of a strap in accordance with the invention;

FIG. 9 is a cross-sectional view illustrating the strap in FIG. 8;

FIG. 10 is a plan view illustrating yet another exemplary embodiment of a strap in accordance with an exemplary embodiment of the invention;

FIG. 11 is a cross-sectional view illustrating the strap in FIG. 10;

FIG. 12 is a plan view illustrating yet another exemplary embodiment of a strap in accordance with the invention; and

FIG. 13 is a cross-sectional view illustrating the strap in FIG. 12.

### DETAILED DESCRIPTION

It will be understood that when an element or layer is referred to as being “on,” “connected to” or “coupled to” another element or layer, the element or layer can be directly on, connected or coupled to another element or layer or intervening elements or layers. In contrast, when an element is referred to as being “directly on,” “directly connected to” or “directly coupled to” another element or layer, there are no intervening elements or layers present. As used herein, connected may refer to elements being physically, electrically and/or fluidly connected to each other. Like numbers refer to like elements throughout. As used herein, the term “and/or” includes any and all combinations of one or more of the associated listed items.

It will be understood that, although the terms first, second, third, etc., may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the invention.

Spatially relative terms, such as “lower,” “upper” and the like, may be used herein for ease of description to describe the relationship of one element or feature to another element(s) or feature(s) as illustrated in the figures. It will be understood that the spatially relative terms are intended to encompass different orientations of the device in use or operation, in addition to the orientation depicted in the figures. For example, if the device in the figures is turned over, elements described as “lower” relative to other elements or features would then be oriented “upper” relative to the other elements or features. Thus, the exemplary term “lower” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises,” “comprising,” “includes” and/or “including,” when used in this specification, specify the presence of stated features, integers, operations, elements, and/or components, but do not preclude the presence or addition of one or more other features, integers, steps, operations, elements, components, and/or groups thereof.

Embodiments of the invention are described herein with reference to cross-section illustrations that are schematic illustrations of idealized embodiments (and intermediate structures) of the invention. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10%, 5% of the stated value.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

A strap may serve as a ground line for generating uniform plasma in a reaction chamber and may be disposed on a lower surface of a susceptor which moves up and down for loading and unloading of a substrate relative to the reaction chamber, The strap may be formed using a flexible metal The strap may be damaged or cut by a stress generated by the moving up and down of the susceptor and/or a strengthening by fluorine permeation during a deposition process within the reaction chamber. When the strap is damaged or cut, the deposition process is stopped and the strap may be replaced by a new strap. Therefore, there remains a need for an improved strap and apparatus employing the strap, for which damage to the strap is reduced or effectively prevented.

Hereinafter, exemplary embodiments will be described in detail with reference to the accompanying drawings.

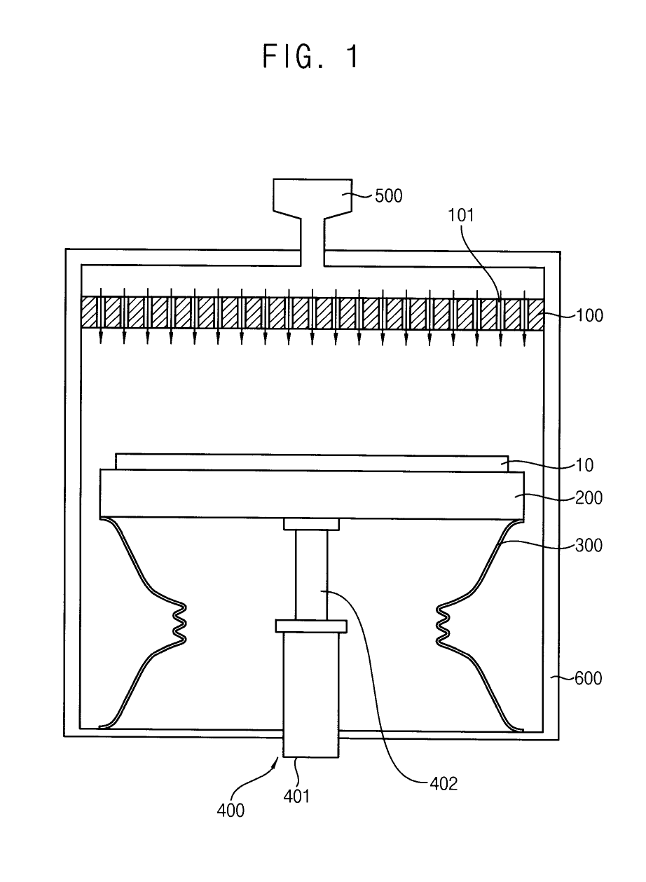

FIG. 1 is a cross-sectional view illustrating an exemplary embodiment of a plasma processing apparatus in accordance with the invention.

Referring to FIG. 1, a plasma processing apparatus includes a first electrode 100, a second electrode 200, a strap 300, a substrate support 400, a gas injection portion 500 and a reaction chamber 600.

The reaction chamber 600 receives the first electrode 100, the second electrode 200, the strap 300 and the substrate support 400.

The first electrode 100 is disposed on an upper inner portion of the reaction chamber 600. A radio frequency (“RF”) power may be applied to the first electrode 100 from a power source (not shown).

A plurality of holes 101 (otherwise referred to as ‘gas holes’) through which a gas passes and from which the gas is sprayed, is defined in the first electrode 100, such as to form a shower head type structure.

The gas injection portion 500 is connected to the first electrode 100. The gas injection portion 500 may supply a deposition gas to the reaction chamber 600 through the gas holes 101 of the first electrode 100. The gas injection portion 500 may be connected to a center portion of the shower head structure of the first electrode 100, but the invention is not limited thereto.

Sizes of the gas holes 101 in a plan view may increase from a center portion to an outer portion of the first electrode 100. In one exemplary embodiment, diameters of the gas holes 101 of the first electrode 100 may increase gradually from the center portion to an outer portion thereof.

The RF power is applied to the first electrode 100 such that the deposition gas passing therethrough may be excited to a plasma state.

The second electrode 200 is disposed on a lower inner portion of the reaction chamber 600. The second electrode 200 may face to the first electrode 100. A substrate 10 is supported on the second electrode 200. The second electrode 200 may serve as a susceptor.

An electric field may be formed between the first electrode 100 and the second electrode 200. In one exemplary embodiment, for example, when the second electrode 200 is an anode, a plasma electron in the reaction chamber 600 moves from the first electrode 100 to the second electrode 200.

The deposition gas which turns into a plasma state, and may be deposited to an upper surface of the substrate 10.

The strap 300 is disposed in the reaction chamber 600. The strap 300 may be connected to a lower surface of the second electrode 200. A pair of the straps 300 may be respectively disposed on opposing sides of the second electrode 200. The strap 300 may be elongated in a cross-sectional direction of the reaction chamber 600. The strap 300 may be bent toward an inner portion of the reaction chamber 600, along a length of the strap 300.

The substrate support 400 is disposed on a lower surface of the second electrode 200. The substrate support 400 may include a cylinder 401 and a cylinder shaft 402. The cylinder shaft 402 may be connected on a lower surface of the second electrode 200 and may move up and down. The cylinder shaft 402 moves up and down, so that the second electrode 200 connected to the cylinder shaft 402 also moves up and down.

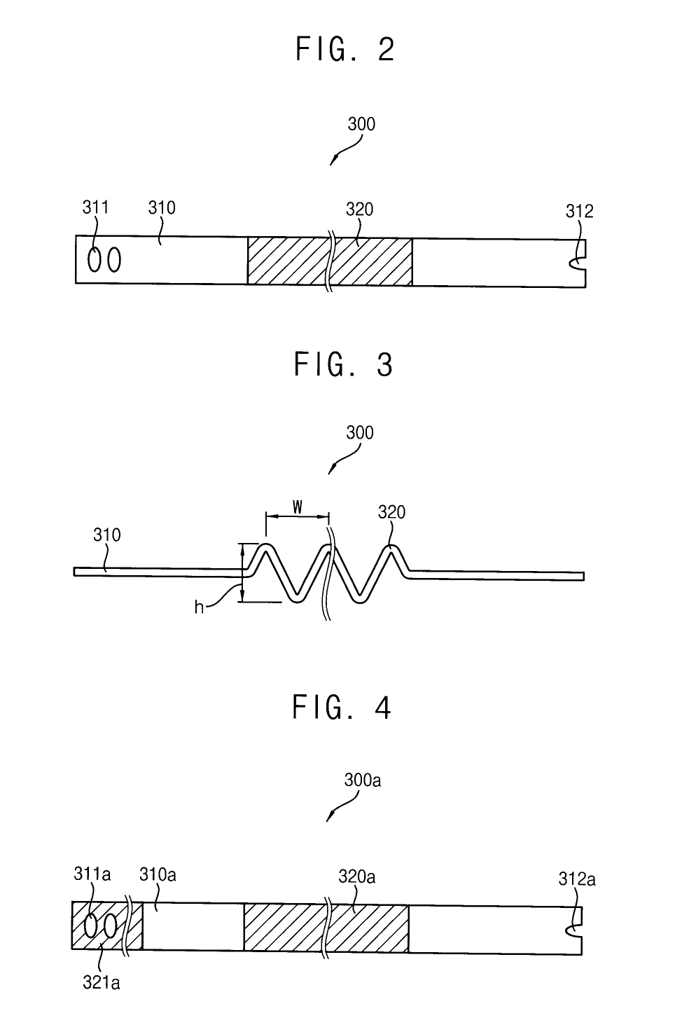

Hereinafter, a structure of the strap 300 will be described in detail with reference to FIGS. 2 and 3.

FIG. 2 is a plan view illustrating an exemplary embodiment of the strap in FIG. 1. FIG. 3 is a cross-sectional view illustrating the strap in FIG. 2.

Referring to FIGS. 1 to 3, the strap 300 includes a main body 310, and a first protrusion pattern 320 defined in the main body 310. Binding parts 311 and 312 may be defined in both of opposing ends of the main body 310. Portions of the main body 310 define both the first protrusion pattern 320 and the binding parts 311 and 312. When the strap 300 is installed in the reaction chamber 600, the main body 310 may be bent toward an inner portion of the reaction chamber 600 from a position in the reaction chamber 600 at which one or both the ends of the strap 300 are secured in the reaction chamber 600. The main body 310 may be bent to form various shapes. Further, at least one protrusion pattern may be defined in and/or by the main body 310. The first protrusion pattern 320 may be defined at a center portion of the main body 310, but the invention is not limited thereto.

The strap 300 is disposed on a lower surface of the second electrode 200. A first end of the strap 300 may be secured to the lower surface of the second electrode 200. The main body 310 of the strap 300 has flexibility. Additionally, the strap 300 serves as a ground wire for making generated plasma uniform in the reaction chamber 600. Therefore, the main body 310 of the strap 300 also has a relatively high electric conductivity.

The main body 310 may include a metal having a relatively high electric conductivity and flexibility. Examples of the metal of the main body 310 may include aluminum (Al), nickel (Ni), etc. In the illustrated exemplary embodiment, the metal may be aluminum.

The first protrusion pattern 320 may be defined by a portion of the main body 310 which is repeatedly bent with respect to a plane of a remaining portion of the main body 310 not including the first protrusion pattern 320. In one exemplary embodiment, for example, the first protrusion pattern 320 may have a sine-shape in a cross-sectional view of the strap 300. The first protrusion pattern 320 may include at least one protrusion. A strap may include only one protrusion pattern, but the invention is not limited thereto.

Referring to FIG. 3, a height ‘h’ of the protrusion of the protrusion pattern 320 may be within a range of about 0.5 centimeter (cm) to about 3 centimeters (cm). The height ‘h’ may be defined as a maximum distance between distal ends of the protrusions defining the first protrusion pattern 320, or a maximum distance between a base and a distal end of one protrusion of the first protrusion pattern 320.

When the height ‘h’ of the protrusion is less than about 0.5 cm, a stress applied to the strap 300 may not be distributed adequately along the strap 300. When the height ‘h’ of the protrusion is more than about 3 cm, an overall cross-sectional thickness of the strap 300 is too thick, so that flexibility of the strap 300 may be decreased.

Referring again to FIG. 3, a width ‘w’ of the protrusion may be within a range of about 0.1 cm to about 3 cm. The width ‘w’ may be defined as a distance between opposing ends of one protrusion, taken along the length of the strap 300.

When the width ‘w’ of the protrusion is less than about 0.1 cm, a stress applied to the strap 300 may not be distributed adequately along the strap 300. When the width ‘w’ of the protrusion is more than about 3 cm, an overall length of the strap 300 is too large, so that a wavelength of the first protrusion pattern 320 is too long.

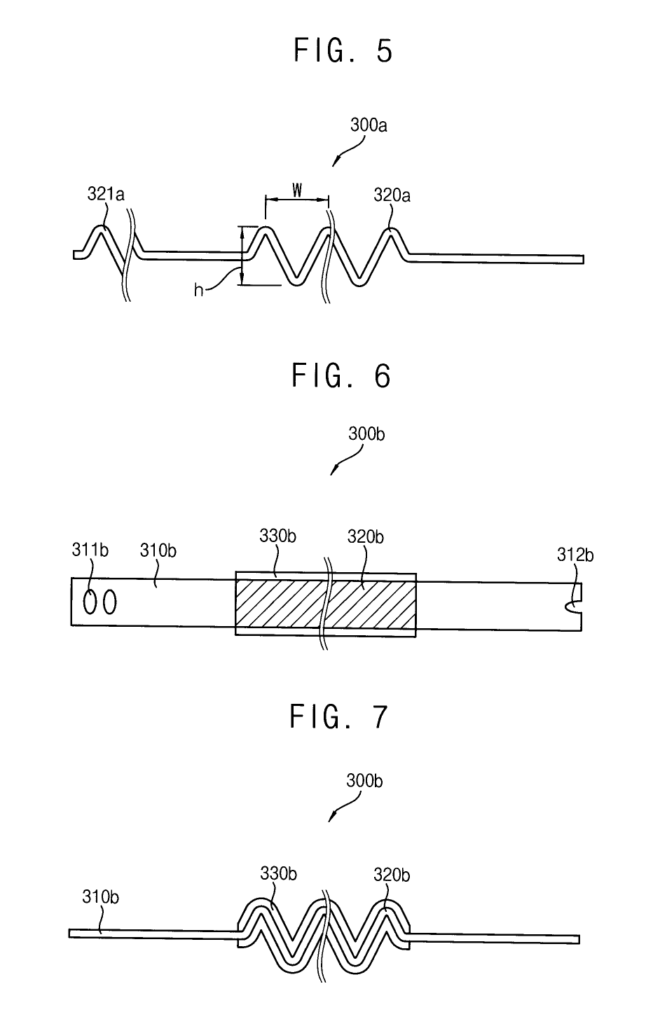

FIG. 4 is a plan view illustrating another exemplary embodiment of a strap in accordance with the invention. FIG. 5 is a cross-sectional view illustrating the strap in FIG. 4.

The strap 300a according to the illustrated exemplary embodiment is substantially the same as the strap 300 in FIGS. 2 and 3, except that the strap 300a further includes a second protrusion pattern adjacent to a first binding part 311a. Thus, the same reference numerals will be used to refer to the same or like parts as those described in FIGS. 2 and 3 and any repetitive explanation concerning the above elements will be omitted.

Referring to FIGS. 1 to 5, the plasma processing apparatus includes a first electrode 100, a second electrode 200, a strap 300a, a substrate support 400, a gas injection 500 and a reaction chamber 600.

The strap 300a may include a first protrusion pattern 320a and a second protrusion pattern 321a. A plurality of binding parts includes a first binding part 311a and a second binding part 312a. The first binding part 311a is disposed at an upper portion of the plasma processing apparatus when the strap 300a is secured in the reaction chamber 600, where a stress and fluorine permeations are relatively strong as compared to other positions within the reaction chamber 600. Thus, the second protrusion pattern 321a is defined in and/or by a portion of the main body 310a adjacent to the first binding part 311a or in which the first binding part 311a is defined.

The main body 310a may be bent to form the second protrusion pattern 321a. In one exemplary embodiment, for example, the second protrusion pattern 321a may have a sine-shape in a cross-sectional view of the strap 300a. The second protrusion pattern 321a may include at least one protrusion.

A height ‘h’ of the protrusion may be within a range of about 0.5 cm to about 3 cm.

When the height ‘h of the protrusion is less than about 0.5 cm, a stress applied to the strap 300 may not be distributed adequately along the strap 300a. When the height ‘h’ of the protrusion is more than about 3 cm, an overall cross-sectional thickness of the strap 300 is too thick, so that flexibility of the strap 300 may be decreased.

A width ‘w’ of the protrusion may be within a range of about 0.1 cm to about 3 cm.

When the width ‘w’ of the protrusion is less than about 0.1 cm, a stress applied to the strap 300 may not be distributed adequately along the strap 300a. When the width ‘w’ of the protrusion is more than about 3 cm, a length of the strap 300 is too large, so that a wavelength of the first and/or second protrusion pattern 320a and 321a is too long.

FIG. 6 is a plan view illustrating still another exemplary embodiment of a strap in accordance with the invention. FIG. 7 is a cross-sectional view illustrating the strap in FIG. 6.

The strap 300b according to the illustrated exemplary embodiment is substantially the same as the strap 300 in FIGS. 2 and 3 except that the strap 300b further includes a first coating layer 330b on a first protrusion pattern 320b. Thus, the same reference numerals will be used to refer to the same or like parts as those described in FIGS. 2 and 3 and any repetitive explanation concerning the above elements will be omitted.

Referring to FIGS. 1, 6 and 7, the plasma processing apparatus includes a first electrode 100, a second electrode 200, a strap 300b, a substrate support 400, a gas injection 500 and a reaction chamber 600.

The strap 300b may include a first coating layer 330b disposed on the first protrusion pattern 320b. The first coating layer 330b may be disposed on both upper and lower surfaces of the main body 310b as illustrated in FIG. 7, and side surfaces of the main body 310b as illustrated in FIG. 6, but the invention is not limited thereto. The first coating layer 330b may expose a remaining portion of the main body 310b, other that the portion at which the first protrusion pattern 320b is defined. The first coating layer 330b may include an engineering plastic, an inorganic material, etc. The coating layers may be disposed on one or both of upper and lower surfaces of the respective protrusion pattern. A plurality of binding parts includes a first binding part 311b and a second binding part 312b.

The strap 300b may be strengthened by fluorine permeation such that a rigidity thereof increases to reduce the flexibility thereof. Strengthening of the strap 300b may be reduced or effectively prevented by the first coating layer 330b.

When the strap 300b including aluminum is exposed to fluorine, fluorine permeates the strap 300b, to form aluminum fluoride (AlF₃). Therefore, the strap 300b may be strengthened.

A crystal structure of aluminum has a face centered cubic (“FCC”) system. When AlF₃ is more than and equal to about 65% of the strap 300b, a crystal structure of AlF₃ has a rhombohedral shape, so that a volume of the strap 300b may increase. Therefore, a stress of the strap 300b may increase.

As the stress and the strengthening of the strap 300b increase, the strap 300b may be broken or may be disconnected from the element of the plasma processing apparatus to which it is coupled, when the strap 300b moves up and down within the reaction chamber 600.

The first coating layer 330b is disposed on the first protrusion pattern 320b of the strap 300b. Accordingly, the stress on the strap 300b may be adequately distributed along the strap 300b, and the strengthening of the strap 300b may be reduced or effectively prevented, and thus the breaking and/or disconnection of the strap 300b may be reduced or effectively prevented.

The first coating layer 330b may include an engineering plastic. The first coating layer 330b reduces or effectively prevents a direct exposure of fluorine to aluminum metal of the strap 300b.

A plasma processing process proceeds in a temperature of more than about 300 degrees Celsius (° C.). Thus, when a coating layer includes a normal organic material, the coating layer including the normal organic material may be decomposed by a relatively high temperature. Therefore, the first coating layer 330b may include an engineering plastic.

In one exemplary embodiment, for example, the engineering plastic may include polyether ether ketone (“PEEK”) and polyaryl ether ketone (“PAEK”), but is not limited thereto.

The engineering plastic has a relatively high impact resistance, a relatively high chemical resistance, a relatively high heat resistance, a relatively high wear resistance, etc. The engineering plastic such as PEEK and PAEK has a relatively high wear resistance.

The PEEK may include a compound represented by Chemical Formula 1. Herein, n is a natural number.

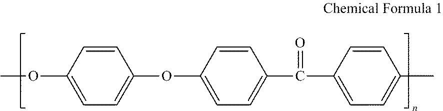

The PAEK may include a compound represented by Chemical Formula 2. Herein, n is a natural number.

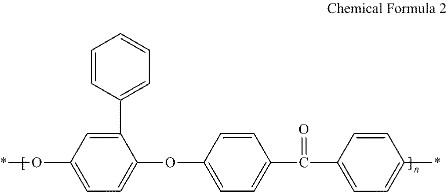

A weight-average molecular weight of the engineering plastic may be within about 10,000 to about 1,000,000 grams per mole (g/mole). The weight-average molecular weight of the engineering plastic may be determined by measuring a melting range of the engineering plastic.

When the weight-average molecular weight of the engineering plastic is less than 10,000 g/mole, a hardness of the first coating layer 330b decreases.

When the weight-average molecular weight of the engineering plastic is more than 1,000,000 g/mole, the engineering plastic rarely melts. Thus, a handling of a material is difficult, so that productivity decreases.

The first coating layer 330b may include an inorganic material. The inorganic material may withstand relatively high temperatures.

In one exemplary embodiment, for example, the inorganic material may include aluminum oxide (Al₂O₃), zirconium oxide (ZrO₂) and yttrium oxide (Y₂O₃), but is not limited thereto.

The first coating layer 330b is disposed on the first protrusion pattern 320b. Although it is not illustrated in the figures, the first coating layer 330b may include a multi-layer structure including lower coating layer and an upper coating layer. In one exemplary embodiment, the lower coating layer may include the engineering plastic and the upper coating layer may include the inorganic material. Alternatively, the lower coating layer may include the inorganic material and the upper coating layer may include the engineering plastic.

In one exemplary embodiment, for example, a cross-sectional thickness of the first coating layer 330b taken in a direction normal to a surface of the main body 310b on which it is disposed, may be within a range of about 0.1 micrometer (μm) to about 200 micrometers (μm).

When a cross-sectional thickness of the first coating layer 330b is less than about 0.1 μm, fluorine permeation may not be effectively prevented. When a cross-sectional thickness of the first coating layer 330b is more than about 200 μm, the first coating layer 330b is too thick, to thereby decrease flexibility of and increase a stress to the strap 300b.

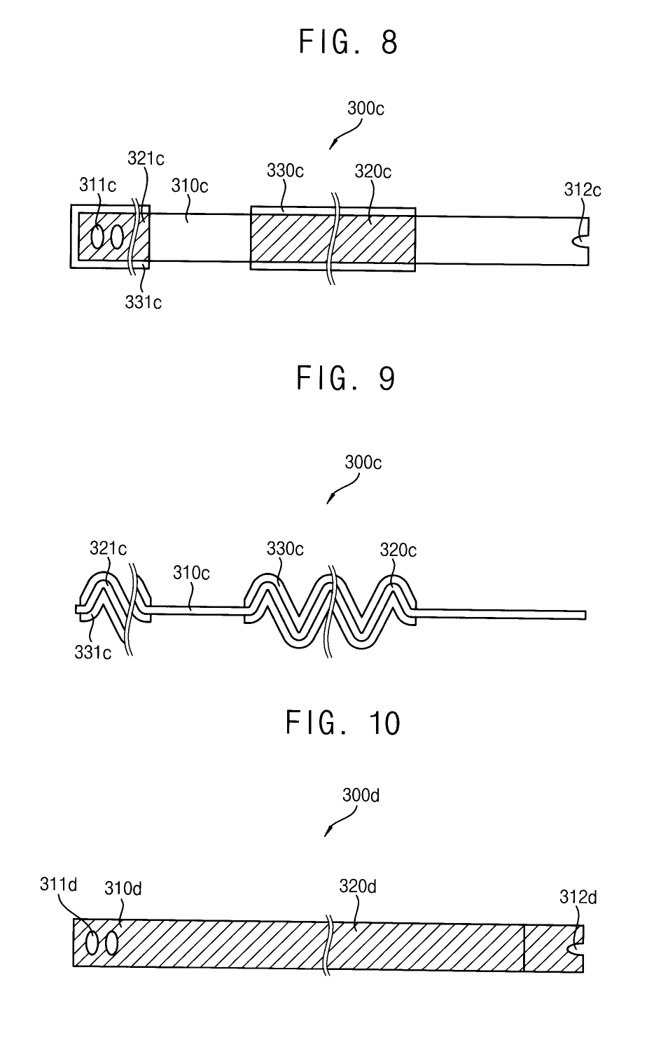

FIG. 8 is a plan view illustrating yet another exemplary embodiment of a strap in accordance with the invention. FIG. 9 is a cross-sectional view illustrating the strap in FIG. 8.

The strap 300c according to the illustrated exemplary embodiment is substantially the same as the strap 300a in FIGS. 4 and 5 except that the strap 300c further includes a first coating layer 330c disposed on a first protrusion pattern 320c and a second coating layer 331c disposed on a second protrusion pattern 321c. Thus, the same reference numerals will be used to refer to the same or like parts as those described in FIGS. 4 and 5 and any repetitive explanation concerning the above elements will be omitted.

The first coating layer 330c and the second coating layer 331c according to the illustrated exemplary embodiment is substantially the same as the first coating layer 330b in FIGS. 6 and 7. Thus, the same reference numerals will be used to refer to the same or like parts as those described in FIGS. 6 and 7 and any repetitive explanation concerning the above elements will be omitted.

Referring to FIGS. 1 to 9, the strap 300c may include a first protrusion pattern 320c and a second protrusion pattern 321c. A plurality of binding parts includes a first binding part 311c and a second binding part 312c. The first binding part 311c is disposed on an upper portion of the plasma processing apparatus when the strap 300c is secured in the reaction chamber 600, where a stress and fluorine permeations are relatively strong as compared to other positions within the reaction chamber 600. Thus, the second protrusion pattern 321c is defined in and/or by a portion of the main body 310c adjacent to the first binding part 311c or in which the first binding part 311c is defined.

The strap 300c may include a first coating layer 330c disposed on the first protrusion pattern 320c. The first coating layer 330c may include an engineering plastic and an inorganic material. The strap 300c may include a second coating layer 331c disposed on the second protrusion pattern 321c. The second coating layer 331c may include an engineering plastic and an inorganic material. The second coating layer 331c may be disposed on both upper and lower surfaces of the main body 310c as illustrated in FIG. 9, and side surfaces and an end surface of the main body 310c as illustrated in FIG. 8, but the invention is not limited thereto. The first coating layer 330b may expose a remaining portion of the main body 310b, other that the portion at which the first protrusion pattern 320b is defined.

The strap 300c may include a first protrusion pattern 320c and a second protrusion pattern 321c. A plurality of binding parts includes a first binding part 311c and a second binding part 312c. The first binding part 311c is disposed on the upper portion of the plasma processing apparatus, so that a relatively large amount of plasma gases contact the first binding part 311c portion of the strap 300c. Thus, fluorine permeations are relatively strong at the first binding part 311c portion of the strap 300c secured at the upper portion of the plasma processing apparatus.

The first coating layer 330c and the second coating layer 331c may be disposed, so that a stress to the strap 300c may be adequately distributed and a strengthening of the strap 300c may be reduced or effectively prevented.

The first coating layer 330c and the second coating layer 331c may include an engineering plastic. In one exemplary embodiment, for example, the engineering plastic includes PEEK and PEAK, but is not limited thereto.

The PEEK may include a compound represented by Chemical Formula 1 described above.

The PEAK may include a compound represented by Chemical Formula 2 described above.

A weight-average molecular weight of the engineering plastic may be within about 10,000 to about 1,000,000 g/mole. The weight-average molecular weight of the engineering plastic may be determined by measuring a melting range of the engineering plastic.

The first coating layer 330c and the second coating layer 331c may include an inorganic material. The inorganic material may withstand relatively high temperatures.

In one exemplary embodiment, for example, the inorganic material may include aluminum oxide (Al₂O₃), zirconium oxide (ZrO₂) and yttrium oxide (Y₂O₃), but is not limited thereto.

The first coating layer 330c is disposed on the first protrusion pattern 320c. Although it is not illustrated in the figures, the first coating layer 330c may include a multi-layer structure including a lower coating layer and an upper coating layer. In one exemplary embodiment, the lower coating layer may include the engineering plastic and the upper coating layer may include the inorganic material. Alternatively, the lower coating layer may include the inorganic material and the upper coating layer may include the engineering plastic.

In one exemplary embodiment, for example, a cross-sectional thickness of the first coating layer 330c may be within a range of about 0.1 μmum to about 200 μmum.

When a cross-sectional thickness of the first coating layer 330c is less than about 0.1 μmum, fluorine permeation may not be effectively prevented. When a cross-sectional thickness of the first coating layer 330c is more than about 200 μmum, the first coating layer 330c is too thick, to thereby decrease flexibility of and increase a stress to the strap 300c.

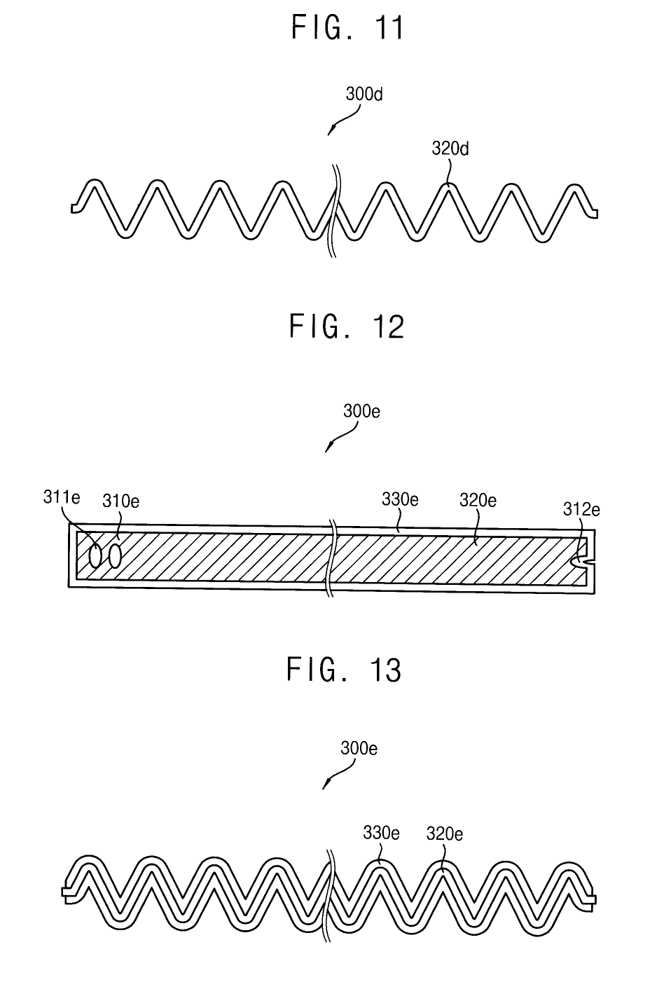

FIG. 10 is a plan view illustrating yet another exemplary embodiment of a strap in accordance with the invention. FIG. 11 is a cross-sectional view illustrating the strap in FIG. 10.

The strap 300d according to the illustrated exemplary embodiment is substantially the same as the strap 300 in FIGS. 2 and 3 except that the strap 300d includes a first protrusion pattern 320d defined in an entirety of a main body 310d. Thus, the same reference numerals will be used to refer to the same or like parts as those described in FIGS. 2 and 3 and any repetitive explanation concerning the above elements will be omitted.

Referring to FIGS. 1 to 10, the plasma processing apparatus includes a first electrode 100, a second electrode 200, a strap 300d, a substrate support 400, a gas injection 500 and a reaction chamber 600.

The strap 300d includes the main body 310d, and a first protrusion pattern 320d defined in a portion of the main body 310d. The main body 310d includes a first binding part 311d and a second binding part 312d. The main body 310d may be bent toward an inner portion of the reaction chamber 600 from a position in the reaction chamber 600 at which one or both the ends of the strap 300d are secured in the reaction chamber 600. The main body 310d may be bent to form various shapes. At least one protrusion pattern may be defined in the main body 310d. The first protrusion pattern 320d may be defined in a whole of the main body 310d.

The first protrusion pattern 320d is defined in an entirety of the main body 310d, so that a stress applied to the strap 300d may be distributed more efficiently.

The strap 300d is disposed on a lower surface of the second electrode 200 and moves up and down, so that the main body 310d of the strap 300d has flexibility. Furthermore, the strap 300d is a ground wire to generate uniform plasma in the reaction chamber 600. Therefore, the main body 310d of the strap 300d also has a relatively high electric conductivity.

Thus, the main body 310d may include a metal having a relatively high electric conductivity and flexibility. The metal may be aluminum (Al) and nickel (Ni).

The first protrusion pattern 320d may be defined by a portion of the main body 310 which is repeatedly bent about a common plane of the main body. In one exemplary embodiment, for example, the first protrusion pattern 320d may have a sine-shape in a cross-sectional view of the strap 300d.

A height ‘h’ of the protrusion of the protrusion pattern 320d may be within a range of about 0.5 cm to about 3 cm.

When the height ‘h’ of the protrusion is less than about 0.5 cm, a stress applied to the strap 300d may not be distributed adequately. When the height ‘h’ of the protrusion is more than about 3 cm, an overall cross-sectional thickness of the strap 300d is too thick, so that flexibility of the strap 300d may be decreased.

A width ‘w’ of the protrusion may be within a range of about 0.1 cm to about 3 cm.

When the width ‘w’ of the protrusion is less than about 0.1 cm, a stress applied to the strap 300d may not be distributed adequately along the strap 300d. When the width ‘w’ of the protrusion is more than about 3 cm, a length of the strap 300d is too large, so that a wavelength of the first protrusion pattern 320d is too long.

FIG. 12 is a plan view illustrating yet another exemplary embodiment of a strap according to the invention. FIG. 13 is a cross-sectional view illustrating the strap in FIG. 12.

The strap 300e according to this exemplary embodiment is substantially the same as the strap 300d in FIGS. 10 and 11 except that the strap 300e further includes a first coating layer 330e disposed on the first protrusion pattern 320e. Thus, the same reference numerals will be used to refer to the same or like parts as those described in FIGS. 10 and 11 and any repetitive explanation concerning the above elements will be omitted.

Referring to FIGS. 1 to 13, the plasma processing apparatus includes a first electrode 100, a second electrode 200, a strap 300e, a substrate support 400, a gas injection 500 and a reaction chamber 600.

Referring to FIGS. 12 and 13, the strap 300e may include a first protrusion pattern 320e and a first coating layer 330e. The first protrusion pattern 320e is defined in an entirety of a main body 310e. A plurality of binding parts includes a first binding part 311e and a second binding part 312e each defined in the main body 310e. The first coating layer 330e is disposed on the first protrusion pattern 320e. The first coating layer 330e includes an engineering plastic and an inorganic material.

The first coating layer 330e is disposed on the first protrusion pattern 320e of the strap 300e. Therefore, disconnection of the strap 300e may be reduced or effectively prevented by dispersing a stress, and reducing or effectively preventing a strengthening of the strap 300e.

The first coating layer 330e may include an engineering plastic. In one exemplary embodiment, for example, the engineering plastic includes PEEK and PEAK, but is not limited thereto.

The PEEK may include a compound represented by Chemical Formula 1 described above.

The PEAK may include a compound represented by Chemical Formula 2 described above.

A weight-average molecular weight (M_{w}) of the engineering plastic may be within about 10,000 to about 1,000,000 g/mole. The weight-average molecular weight of the engineering plastic may be determined by measuring a melting range of the engineering plastic.

The first coating layer 330e may include an inorganic material. The inorganic material may withstand a relatively high temperature.

In one exemplary embodiment, for example, the inorganic material may include aluminum oxide (Al₂O₃), zirconium oxide (ZrO₂) and yttrium oxide (Y₂O₃).

The first coating layer 330e is disposed on the first protrusion pattern 320e. Although it is not illustrated in the figures, the first coating layer 330b may include a multi-layer structure including a lower coating layer and an upper coating layer. The lower coating layer may include the engineering plastic and the upper coating layer may include the inorganic material. Alternatively, the lower coating layer may include the inorganic material and the upper coating layer may include the engineering plastic.

In one exemplary embodiment, for example, a cross-sectional thickness of the first coating layer 330e may be within a range of about 0.1 μm to about 200 μm.

When a cross-sectional thickness of the first coating layer 330e is less than about 0.1 μm, fluorine permeation may not be effectively prevented. When a cross-sectional thickness of the first coating layer 330e is more than about 200 μm, the first coating layer 330e is too thick, to thereby decrease flexibility of and increase a stress to the strap 300e.

An exemplary embodiment of a binding part may include an enclosed opening defined in the main body of the strap, but the invention is not limited thereto. The binding part may also include a recess extending inwardly from an edge of the main body of the strap. A binding part may include a single opening or recess, or may include a group of openings or recessed, as appropriate for securing the strap in the plasma processing apparatus. In the illustrated exemplary embodiments, portions of the main body define the binding part.

In accordance with one or more exemplary embodiment of the invention, a strap used in a plasma processing apparatus includes a protrusion pattern, and a coating layer formed on the protrusion pattern. Therefore, stress applied to the strap may be effectively distributed along the strap, and a disconnection of the strap may be reduced or effectively prevented by reducing or effectively preventing a strengthening by fluorine permeation. Thus, an interruption of a deposition process is decreased since replacement of the strap may not be necessary.

Although exemplary embodiments of the invention have been described, it is understood that the invention should not be limited to these exemplary embodiments and various changes and modifications can be made by one of those ordinary skilled in the art within the spirit and scope of the invention as hereinafter claimed.

The foregoing is illustrative of the invention and is not to be construed as limiting thereof. Although a few exemplary embodiments of the invention have been described, those skilled in the art will readily appreciate that many modifications are possible in the exemplary embodiments without materially departing from the novel teachings and advantages of the invention. Accordingly, all such modifications are intended to be included within the scope of the invention as defined in the claims. In the claims, means-plus-function clauses are intended to cover the structures described herein as performing the recited function and not only structural equivalents but also equivalent structures. Therefore, it is to be understood that the foregoing is illustrative of the invention and is not to be construed as limited to the specific exemplary embodiments disclosed, and that modifications to the disclosed exemplary embodiments, as well as other exemplary embodiments, are intended to be included within the scope of the appended claims. The invention is defined by the following claims, with equivalents of the claims to be included therein.

What is claimed is:

1. A strap for a plasma processing apparatus, comprising:
a main body,
a binding part defined in the main body at opposing ends thereof; and
a protrusion pattern defined in the main body and comprising a protrusion.

2. The strap of claim 1, wherein the main body comprises aluminum.

3. The strap of claim 1, wherein a height of the protrusion is within a range of about 0.5 centimeter to about 3 centimeters.

4. The strap of claim 1, wherein a width of the protrusion along a length of the strap is within a range of about 0.1 centimeter to about 3 centimeters.

5. The strap of claim 1, further comprising:
a coating layer on the protrusion pattern and comprising an engineering plastic or an inorganic material.

6. The strap of claim 5, wherein the coating layer comprises a plurality of layers comprising:
a first layer on the protrusion pattern and comprising the engineering plastic; and
a second layer on the first layer and comprising the inorganic material.

7. The strap of claim 5, wherein the coating layer comprises a plurality of layers comprising:
a first layer on the protrusion pattern and comprising the inorganic material; and
a second layer on the first layer and comprising the engineering plastic.

8. The strap of claim 5, wherein a cross-sectional thickness of the coating layer is within a range of about 0.1 micrometer to about 200 micrometers.

9. The strap of claim 5, wherein the engineering plastic comprises polyether ether ketone or polyether aryl ketone.

10. The strap of claim 5, wherein the inorganic material comprises Al₂O₃, ZrO₂ or Y₂O₃.

11. The strap of the claim 1, wherein the protrusion pattern is defined in an entirety of the main body.

12. The strap of the claim 11, further comprising:
a coating layer on an entirety of the protrusion pattern, and comprising an engineering plastic or an inorganic material.

13. A plasma processing apparatus comprising:
a first electrode to which a radio frequency power is applied;
a second electrode facing the first electrode;
a strap on a lower surface of the second electrode, and comprising:
a main body,
a binding part defined in the main body at opposing ends thereof, and
a protrusion pattern defined in the main body and comprising a protrusion;
a substrate support on a lower surface of the second electrode; and
a reaction chamber which receives the first electrode, the second electrode, the strap and the substrate support therein.

14. The plasma processing apparatus of claim 13, further comprising:
a gas injection portion on an upper surface of the first electrode.

15. The plasma processing apparatus of claim 13, wherein the second electrode is a susceptor.

16. The plasma processing apparatus of claim 13, wherein a height of the protrusion is within a range of about 0.5 centimeter to about 3 centimeters.

17. The plasma processing apparatus of claim 13, wherein a width of the protrusion along a length of the strap is within a range of about 0.1 centimeter to about 3 centimeters.

18. The plasma processing apparatus of claim 13, further comprising:
a coating layer on the protrusion pattern and comprising an engineering plastic or an inorganic material.

19. The plasma processing apparatus of claim 18, wherein the engineering plastic comprises polyether ether ketone or polyether aryl ketone.

20. The plasma processing apparatus of claim 18, wherein the inorganic material comprises Al₂O₃, ZrO₂ or Y₂O₃.
